(19) United States
(12) Patent Application Publication
(10) Pub. No.: US 2007/0215044 A1
(43) Pub. Date: Sep. 20, 2007

(54) SUBSTRATE PROCESSING APPARATUS, DEPOSIT MONITORING APPARATUS, AND DEPOSIT MONITORING METHOD

(75) Inventor: Yohei YAMAZAWA, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/685,318

(22) Filed: Mar. 13, 2007

Related U.S. Application Data
(60) Provisional application No. 60/788,089, filed on Apr. 3, 2006.

(30) Foreign Application Priority Data
Mar. 20, 2006 (JP) 2006-077265

(51) Int. Cl. C23C 14/54; B05C 11/00

(52) U.S. Cl. 118/665; 427/9

(57) ABSTRACT

A substrate processing apparatus enable fouling due to deposit to be monitored in real time. To monitor deposit attached to an inner wall surface of a processing chamber in which processing is carried out on a substrate, a deposit monitoring apparatus of the substrate processing apparatus includes a sensor for measuring a capacitance between two conductors spaced apart from each other and both connected to the sensor. The capacitance between the conductors increases with increase in an mount of deposit and reflects the state of fouling due to deposit.

### BACKGROUND OF THE INVENTION

1. Field of the Invention

The present invention relates to a substrate processing apparatus, a deposit monitoring apparatus, and a deposit monitoring method, and in particular relates to a substrate processing apparatus that enables monitoring of deposit attached to an inner wall surface of a processing chamber (chamber) in which predetermined processing is carried out on substrates to be processed.

2. Description of the Related Art

In plasma processing for manufacturing semiconductor chips, etching of a thin film formed on a semiconductor wafer (hereinafter referred to merely as “wafer”) as a substrate to be processed, or CVD (chemical vapor deposition) in which a predetermined material is deposited on the wafer so as to form a thin film, is carried out in a chamber housing the wafer.

CVD is a process in which a thin film of a predetermined material is formed on a wafer, and hence a deposit of the predetermined material inevitably becomes attached to an inner wall of the chamber. On the other hand, in etching, a thin film formed on a wafer is progressively removed through chemical reaction or sputtering, and reaction product produced at this time becomes attached as deposit to the inner wall of the chamber. In this way, the inner wall of the chamber is fouled with deposit during the plasma processing. If the inner wall of the chamber is severely fouled with deposit, then the distribution of plasma in the chamber is affected, and hence the reproducibility of the plasma processing worsens.

In a semiconductor chip mass production plant, cleaning of the interior of a chamber of a substrate processing apparatus used as a semiconductor chip manufacturing apparatus is thus carried out periodically so as to maintain the reproducibility of the plasma processing in the substrate processing apparatus.

Moreover, there have been proposed statistical techniques for analyzing data such as the current or voltage of radio frequency electrical power supplied into the chamber for carrying out the plasma processing, the data having been obtained over a plurality of times of carrying out the plasma processing (see, for example, Japanese Laid-open Patent Publication (Kokai) No. 2004-335841 and Japanese Laid-open Patent Publication (Kokai) No. 2003-163200). By using such a statistical technique, the environment in the chamber including the state of fouling due to deposit in the chamber can be predicted based on the analysis results. Moreover, the cleaning period, specifically the time to commence cleaning, can be decided based on this prediction.

However, with such a statistical technique, to improve the accuracy of the prediction of the environment in the chamber, a large amount of data must be obtained, which takes time, and hence the analysis results cannot be obtained in real time. In particular, to prevent worsening of the reproducibility of the plasma processing, it is desired to detect the beginning of fouling of the inner wall of the chamber due to deposit, i.e. the beginning of attachment of deposit onto the inner wall of the chamber, in real time, and hence a statistical technique as above does not meet actual needs.

### SUMMARY OF THE INVENTION

It is an object of the present invention to provide a substrate processing apparatus, a deposit monitoring apparatus, and a deposit monitoring method, which enable fouling due to deposit to be monitored in real time.

To attain the above object, in a first aspect of the present invention, there is provided a substrate processing apparatus comprising a processing chamber in which predetermined processing is carried out on a substrate to be processed, and a deposit monitoring apparatus that monitors deposit attached to an inner wall surface of the processing chamber, wherein the deposit monitoring apparatus comprises a first conductor at least part of which is provided in the processing chamber, a second conductor that is disposed separated from the first conductor, and a sensor that is connected to the first conductor and the second conductor and obtains data relating to a capacitance between the first conductor and the second conductor.

According to the first aspect of the present invention, the first conductor and the second conductor are disposed separated from one another, and are connected to a sensor that obtains data relating to the capacitance. If deposit, which generally has a high permittivity, becomes attached to the surface of the first conductor and the second conductor, then a capacitor having a high capacitance is formed, data relating to this capacitance, for example the value of the capacitance, being obtained by the sensor. The obtained data relating to the capacitance thus reflects the state of fouling due to deposit, and hence fouling due to deposit can be monitored in real time.

Moreover, the monitoring of deposit can be carried out merely by providing in the processing chamber at least part of a conductor connected to the sensor. The deposit monitoring apparatus can thus be constructed inexpensively, and the construction can be simplified.

Preferably, the sensor comprises a capacitance meter that measures the capacitance between the first conductor and the second conductor.

In this case, the sensor comprises a capacitance meter that measures the capacitance between the first conductor and the second conductor. As a result, the state of fouling due to deposit can easily be converted into a numerical value.

Preferably, the sensor comprises an oscillator constituted from an oscillating element that oscillates at a predetermined frequency, and a resonance circuit that resonates at the frequency of the oscillating element.

In this case, the sensor comprises an oscillator including a resonance circuit that resonates at the frequency of an oscillating element. If the capacitance of the above capacitor changes due to attachment of deposit, then the resonant state of the resonance circuit is affected. As a result, beginning of fouling due to deposit can be detected in real time.

Preferably, the substrate processing apparatus further comprises a first dielectric that surrounds the first conductor, and a second dielectric that surrounds the second conductor.

In this case, each of the first conductor and the second conductor is surrounded by a dielectric. As a result, the surface of each of the first conductor and the second conductor can be prevented from being exposed to the interior of the processing chamber. In the case, in particular, that the substrate processing apparatus is an apparatus in which processing using plasma can be carried out, abnormal electrical discharge can thus be prevented from occurring when the plasma is produced.

Preferably, the substrate processing further comprises a third dielectric provided between the first and second conductors and the inner wall of the processing chamber such that a capacitance between the first and second conductors and the inner wall of the processing chamber is less than the capacitance between the first conductor and the second conductor.

In this case, a dielectric is provided between the first and second conductors and the inner wall of the processing chamber. As a result, a gap can be secured between the first conductor and the inner wall of the processing chamber, whereby the capacitance between the first and second conductors and the inner wall of the processing chamber can be made to be less than the capacitance between the first conductor and the second conductor. In the case, in particular, that the inner wall of the processing chamber is made of a conductor, another capacitor can thus be prevented from being formed by the first conductor and deposit attached to the inner wall of the processing chamber, and hence a measurement error of the sensor can be reduced, and thus the reliability can be improved.

Preferably, the substrate processing apparatus further comprises a first dielectric that surrounds the first conductor, and the second conductor comprises part of the processing chamber.

In this case, the first conductor is surrounded by a dielectric. As a result, the surface of the first conductor can be prevented from being exposed to the interior of the processing chamber. Moreover, the second conductor comprises part of the processing chamber. As a result, part of the processing chamber can be used as a ground that specifies a reference potential for the above capacitor. The construction of the deposit monitoring apparatus can thus be simplified.

Preferably, the sensor is provided outside the processing chamber.

In this case, the sensor is provided outside the processing chamber. As a result, the deposit monitoring apparatus can easily be detached from the processing chamber.

Preferably, the processing chamber has formed therein a groove for embedding at least the first conductor out of the first conductor and the second conductor.

In this case, a groove for embedding the first conductor and/or the second conductor is formed in the processing chamber. As a result, the first conductor and/or the second conductor can be prevented from protruding out from a surface of the processing chamber. In the case, in particular, that the substrate processing apparatus is an apparatus in which processing using plasma can be carried out, abnormal electrical discharge can thus be prevented from occurring when the plasma is produced.

Preferably, the substrate processing apparatus further comprises a detector that detects attachment of the deposit based on the obtained data relating to the capacitance.

In this case, attachment of deposit is detected based on the obtained data relating to the capacitance. As a result, fouling due to deposit can be monitored in real time reliably.

Preferably, the substrate processing apparatus further comprises a controller that carries out feedback control in accordance with detection results from the detector.

In this case, feedback control is carried out in accordance with detection results from the detector. As a result, the reliability of automatic control of the substrate processing apparatus can be improved.

To attain the above object, in a second aspect of the present invention, there is provided a deposit monitoring apparatus that monitors deposit attached to an inner wall surface of a processing chamber in which predetermined processing is carried out on a substrate to be processed, the deposit monitoring apparatus comprising a first conductor at least part of which is provided in the processing chamber, a second conductor that is disposed separated from the first conductor, and a sensor that is connected to an end of the first conductor and an end of the second conductor and obtains data relating to a capacitance between the first conductor and the second conductor.

To attain the above object, in a third aspect of the present invention, there is provided a deposit monitoring method for monitoring deposit attached to an inner wall surface of a processing chamber in which predetermined processing is carried out on a substrate to be processed, the deposit monitoring method comprising a data obtaining step of obtaining data relating to a capacitance between a first conductor at least part of which is provided in the processing chamber, and a second conductor that is disposed separated from the first conductor

The above and other objects, features, and advantages of the invention will become more apparent from the following detailed description taken in conjunction with the accompanying drawings.

### BRIEF DESCRIPTION OF THE DRAWINGS

FIG. 1 is a sectional view schematically showing the construction of a substrate processing apparatus according to an embodiment of the present invention;

FIG. 2 is a sectional view schematically showing the construction of a deposit monitoring apparatus installed in an inner wall of a chamber appearing in FIG. 1;

FIG. 3 is a sectional view taken along line III-III in FIG. 2;

FIG. 4 is a sectional view schematically showing the construction of a first variation of the deposit monitoring apparatus shown in FIG. 2;

FIG. 5 is a graph showing a waveform of a current measured by an ammeter of an oscillator appearing in FIG. 4; and

FIG. 6 is a sectional view schematically showing the construction of a second variation of the deposit monitoring apparatus shown in FIG. 2.

### DESCRIPTION OF THE PREFERRED EMBODIMENTS

Embodiments of the present invention will be described in detail below with reference to the drawings.

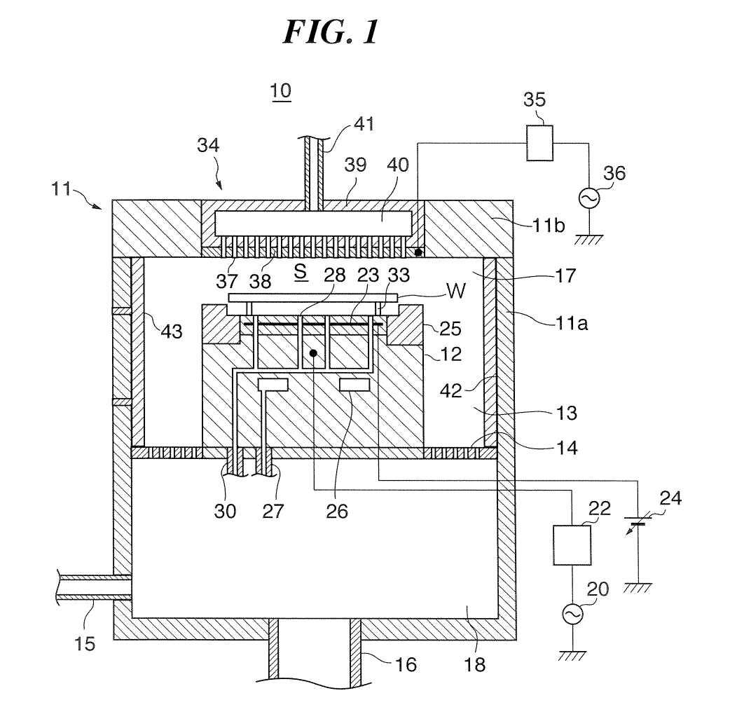

FIG. 1 is a sectional view schematically showing the construction of a substrate processing apparatus according to an embodiment of the present invention. The substrate processing apparatus is constructed such as to carry out etching processing on semiconductor wafers as substrates to be processed.

As shown in FIG. 1, the substrate processing apparatus 10 has a cylindrical chamber 11 (processing chamber) housing a semiconductor wafer (hereinafter referred to merely as a “wafer”) W having a diameter of, for example, 300 mm. A cylindrical susceptor 12 is disposed in the chamber 11 as a stage on which the wafer W is mounted.

In the substrate processing apparatus 10, a side exhaust path 13 that acts as a flow path through which gas above the susceptor 12 is exhausted out of the chamber 11 is formed between an inner wall 11a of the chamber 11 and a side face of the susceptor 12. A baffle plate 14 is disposed part way along the side exhaust path 13.

The baffle plate 14 is a plate-shaped member having a large number of holes therein, and acts as a partitioning plate that partitions the chamber 11 into an upper portion and a lower portion. Plasma, described below, is produced in the upper portion (hereinafter referred to as the “reaction chamber”) 17 of the chamber 11 partitioned by the baffle plate 14. The susceptor 12 is disposed on a bottom portion of the reaction chamber 17. Moreover, a roughing exhaust pipe 15 and a main exhaust pipe 16 that exhaust gas out from the chamber 11 are opened to the lower portion (hereinafter referred to as the “manifold”) 18 of the chamber 11. The roughing exhaust pipe 15 has a DP (dry pump) (not shown) connected thereto, and the main exhaust pipe 16 has a TMP (turbo-molecular pump) (not shown) connected thereto. Moreover, the baffle plate 14 captures or reflects ions and radicals produced in a processing space S, described below, in the reaction chamber 17, thus preventing leakage of the ions and radicals into the manifold 18.

The roughing exhaust pipe 15 and the main exhaust pipe 16 exhaust gas in the reaction chamber 17 out of the chamber 11 via the manifold 18. Specifically, the roughing exhaust pipe 15 reduces the pressure in the chamber 11 from atmospheric pressure down to a low vacuum state, and the main exhaust pipe 16 is operated in collaboration with the roughing exhaust pipe 15 to reduce the pressure in the chamber 11 from atmospheric pressure down to a high vacuum state (e.g. a pressure of not more than 133 Pa (1 Torr)), which is at a lower pressure than the low vacuum state.

A lower radio frequency power source 20 is connected to the susceptor 12 via a matcher 22. The lower radio frequency power source 20 supplies predetermined radio frequency electrical power to the susceptor 12. The susceptor 12 thus acts as a lower electrode. The matcher 22 reduces reflection of the radio frequency electrical power from the susceptor 12 so as to maximize the efficiency of the supply of the radio frequency electrical power into the susceptor 12.

A disk-shaped ESC electrode plate 23 comprised of an electrically conductive film is provided in an upper portion of the susceptor 12. A DC power source 24 is electrically connected to the ESC electrode plate 23. A wafer W is attracted to and held on an upper surface of the susceptor 12 through a Johnsen-Rahbek force or a Coulomb force generated by a DC voltage applied to the ESC electrode plate 23 from the DC power source 24. Moreover, an annular focus ring 25 is provided on an upper portion of the susceptor 12 so as to surround the wafer W attracted to and held on the upper surface of the susceptor 12. The focus ring 25 is exposed to the processing space S, and focuses the plasma in the processing space S toward a surface of the wafer W, thus improving the efficiency of the etching processing.

An annular coolant chamber 26 that extends, for example, in a circumferential direction of the susceptor 12 is provided inside the susceptor 12. A coolant, for example cooling water or a Galden® fluid, at a predetermined temperature is circulated through the coolant chamber 26 via coolant piping 27 from a chiller unit (not shown). A processing temperature of the wafer W attracted to and held on the upper surface of the susceptor 12 is controlled through the temperature of the coolant.

A plurality of heat-transmitting gas supply holes 28 are opened to a portion of the upper surface of the susceptor 12 on which the wafer W is attracted and held (hereinafter referred to as the “attracting surface”) The heat-transmitting gas supply holes 28 are connected to a heat-transmitting gas supply unit (not shown) by a heat-transmitting gas supply line 30. The heat-transmitting gas supply unit supplies helium gas as a heat-transmitting gas via the heat-transmitting gas supply holes 28 into a gap between the attracting surface of the susceptor 12 and a rear surface of the wafer W. The helium gas supplied into the gap between the attracting surface of the susceptor 12 and the rear surface of the wafer W transmits heat from the wafer W to the susceptor 12.

A plurality of pusher pins 33 are provided in the attracting surface of the susceptor 12 as lifting pins that can be made to project out from the upper surface of the susceptor 12. The pusher pins 33 are connected to a motor (not shown) by a ball screw (not shown), and can be made to project out from the attracting surface of the susceptor 12 through rotational motion of the motor, which is converted into linear motion by the ball screw. The pusher pins 33 are housed inside the susceptor 12 when a wafer W is being attracted to and held on the attracting surface of the susceptor 12 so that the wafer W can be subjected to the etching processing, and are made to project out from the upper surface of the susceptor 12 so as to lift the wafer W up away from the susceptor 12 when the wafer W is to be transferred out from the chamber 11 after having been subjected to the etching processing.

A gas introducing shower head 34 (gas introducing apparatus) is disposed in a ceiling portion lib of the chamber 11 facing the susceptor 12 with the reaction chamber 17 therebetween. An upper radio frequency power source 36 is connected to the gas introducing shower head 34 via a matcher 35. The upper radio frequency power source 36 supplies predetermined radio frequency electrical power to the gas introducing shower head 34. The gas introducing shower head 34 thus acts as an upper electrode. The matcher 35 has a similar function to the matcher 22, described earlier.

The gas introducing shower head 34 has a ceiling electrode plate 38 having a large number of gas holes 37 therein, and an electrode support 39 on which the ceiling electrode plate 38 is detachably supported. A buffer chamber 40 is provided inside the electrode support 39. A processing gas introducing pipe 41 is connected to the buffer chamber 40. A processing gas supplied from the processing gas introducing pipe 41 into the buffer chamber 40 is supplied by the gas introducing shower head 34 into the chamber 11 (the reaction chamber 17) via the gas holes 37.

A deposit shield 43 is disposed as a side wall component on the inner wall 11a of the chamber 11 such as to cover the inner wall 11a and face onto the processing space S between the susceptor 12 and the gas introducing shower head 34. The deposit shield 43 is a cylindrical component made of an insulating material such as yttria (Y₂O₃), and is disposed such as to surround the susceptor 12.

Radio frequency electrical power is supplied to the susceptor 12 and the gas introducing shower head 34 in the chamber 11 of the substrate processing apparatus 10 as described above so as to apply radio frequency electrical power into the processing space S, whereupon the processing gas supplied into the processing space S from the gas introducing shower head 34 is turned into high-density plasma, whereby ions and radicals are produced; the wafer W is subjected to the etching processing by the ions and so on.

Operation of the component elements of the substrate processing apparatus 10 described above is controlled in accordance with a program for the etching processing by a CPU of a control unit (not shown) of the substrate processing apparatus 10.

In the substrate processing apparatus 10, when a wafer W is subjected to the etching processing, the ions and so on react with matter present on the surface of the wafer so that a reaction product is produced. The reaction product becomes attached as deposit to the deposit shield 43, and the inner wall 11a and the ceiling portion 11b of the chamber 11, and then the attached reaction product is detached during subsequent etching processing or the like, thus forming particles. The particles float through the reaction chamber 17, in particular the processing space S, and thus become attached as deposit to the surface of a wafer W. For the substrate processing apparatus 10, cleaning of the interior of the chamber 11 must thus be carried out to remove such deposit.

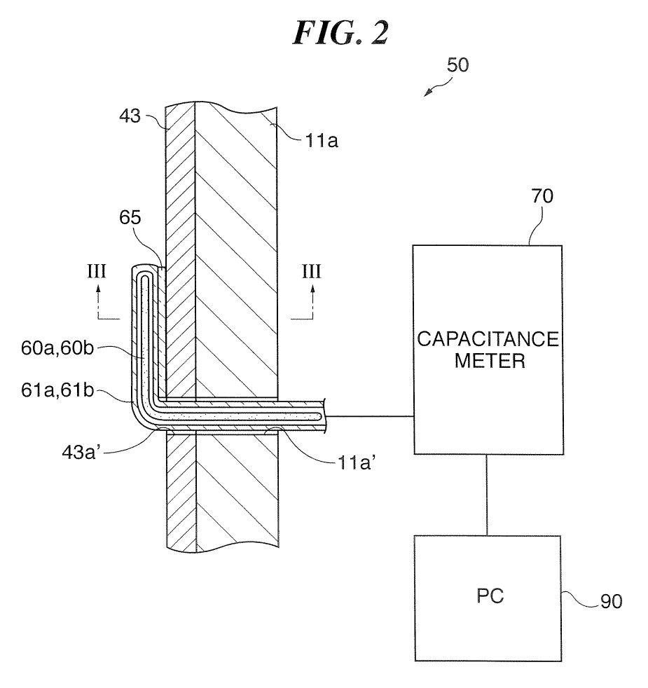

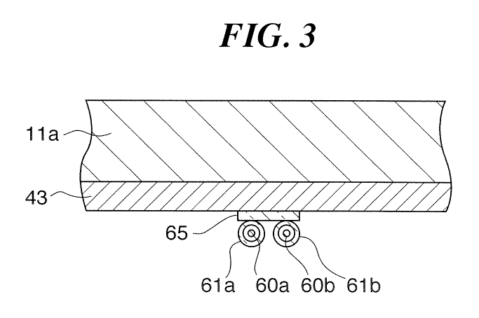

FIG. 2 is a sectional view schematically showing the construction of a deposit monitoring apparatus installed in the inner wall 11a of the chamber 11 appearing in FIG. 1, and FIG. 3 is a sectional view taken along line III-III in FIG. 2.

The deposit monitoring apparatus 50 shown in FIG. 2 monitors deposit attached to a surface of the inner wall 11a of the chamber 11. The deposit monitoring apparatus 50 is comprised of a pair of conductive wires 60a and 60b (first and second conductors) (see FIG. 3) each made of a conductive material such as a copper wire of diameter, for example, 0.9 mm, and a capacitance meter 70 as a sensor connected to one end of each of the conductive wires 60a and 60b. The conductive wires 60a and 60b act as a sensor head for the capacitance meter 70. By increasing the diameter of the conductive wires 60a and 60b, the detection sensitivity of the capacitance meter 70 can thus be improved.

As shown in FIG. 2, the conductive wires 60a and 60b, and quartz pipes 61a and 61b surrounding the conductive wires 60a and 60b are provided such as to pass through a narrow hole 11a′ formed in the inner wall 11a of the chamber 11 and a narrow hole 43a′ formed in the deposit shield 43.

Each of the quartz pipes 61a and 61b is comprised of a tubular member having, for example, an outside diameter of 1.2 mm, an inside diameter of 1.0 mm, and a thickness of 0.1 mm. The pair of quartz pipes 61a and 61b are disposed parallel to one another separated from one another by a gap of, for example, 0.3 mm. The conductive wires 60a and 60b are thus disposed substantially parallel to one another separated from one another by a gap of 0.5 to 0.7 mm, so as to constitute a capacitor having a gap (an air layer) between a pair of electrodes. The gap between the quartz pipes 61a and 61b is preferably set to a value such that reaction product, particles and so on produced in the chamber 11 can infiltrate in between the quartz pipes 61a and 61b; the smaller this gap, the greater the detection sensitivity of the capacitance meter 70 can be made.

A quartz plate 65 having a thickness of, for example, 2 mm is provided between the quartz pipes 61a and 61b and the deposit shield 43. The quartz plate 65 is not limited to having a thickness of 2 mm, but is preferably a thickness such that the capacitance between the conductive wires 60a and 60b and the deposit shield 43 is less than the capacitance between the conductive wire 60a and the conductive wire 60b. As a result, a measurement error of the capacitance meter 70 can be reduced and hence the reliability can be improved.

The quartz pipes 61a and 61b and the quartz plate 65 are each made of a dielectric material having a lower permittivity than the deposit such as particles produced in the chamber 11 (first to third dielectrics). The quartz pipes 61a and 61b prevent a surface of each of the conductive wires 60a and 60b from being exposed to the interior of the chamber 11, and hence abnormal electrical discharge can be prevented from occurring when the plasma is produced. The quartz plate 65 prevents deposit from infiltrating in between the conductive wires 60a and 60b and the deposit shield 43, so as to prevent the conductive wires 60a and 60b and the deposit shield 43 from forming another capacitor, whereby the measurement error of the capacitance meter 70 can be reduced and hence the reliability can be improved.

When installing the conductive wires 60a and 60b, first the quartz plate 65 is disposed on a surface of the deposit shield 43, then the quartz pipes 61a and 61b are disposed on the quartz plate 65, and finally the conductive wires 60a and 60b are inserted into the quartz pipes 61a and 61b As a result, the conductive wires 60a and 60b can be installed easily.

The capacitance meter 70 is for obtaining data relating to the capacitance of the capacitor formed by the conductive wires 60a and 60b, specifically for measuring the value of the capacitance of the capacitor formed by the conductive wires 60a and 60b. The capacitance meter 70 may be a commercially available one, which can be readily procured.

The capacitance meter 70 is connected to a personal computer (PC) 90 that acts as a controller for the substrate processing apparatus 10 shown in FIG. 1. The measured value of the capacitance is inputted into the PC 90. The PC 90 carries out feedback control of automatically controlling the substrate processing apparatus 10 based on the data inputted from the capacitance meter 70. In the feedback control, for example cleaning of the interior of the chamber 11 is carried out, or processing conditions for the etching processing to be carried out on a wafer W are changed. As a result, the reliability of automatic control of the substrate processing apparatus 10 can be improved.

Following is a description of operation of the deposit monitoring apparatus 50 shown in FIG. 2.

The capacitance meter 70 is always measuring the value of the capacitance of the capacitor formed by the conductive wires 60a and 60b, and inputs the measurement results into the PC 90 as data.

Here, while a wafer W is being subjected to the etching processing in the chamber 11, reaction product, particles and so on produced in the chamber 11 become attached as deposit to a surface of each of the quartz pipes 61a and 61b. In this case, the deposit attached to the surface of each of the quartz pipes 61a and 61b, in particular the surface of each of the quartz pipes 61a and 61b between the conductive wires 60a and 60b, generally has a higher permittivity than air, and hence acts as a dielectric layer in place of the air layer in the capacitor formed by the conductive wires 60a and 60b. Because this dielectric layer has a higher permittivity than the air layer, the value of the capacitance measured by the capacitance meter 70 increases. That is, the change in the capacitance of the capacitor is closely related to the amount of the deposit forming the dielectric layer. The value of the capacitance measured by the capacitance meter 70 thus indicates the state of fouling due to deposit.

When the value of the capacitance inputted from the capacitance meter 70 has changed greatly, for example has changed from 200 pF to 210 pF, the PC 90 determines that beginning of fouling has occurred which indicates that attachment of deposit has begun, and carries out cleaning of the interior of the chamber 11 as the feedback control at a suitable timing after implementation of the etching processing has been completed. The PC 90 may also forcibly terminate the etching processing during implementation thereof if it is determined that the change in the capacitance has exceeded a threshold value, for example 250 pF. Moreover, during the cleaning of the interior of the chamber 11 by dry cleaning using plasma, the value of the capacitance inputted from the capacitance meter 70 decreases, for example, from 210 pF to 200 pF. At this time, the PC 90 may determine that the value of the capacitance has returned to the value of the capacitance before attachment of deposit onto the chamber 11 began, and determine this as an end point for the dry cleaning that is being implemented, and thus terminate the dry cleaning that is being implemented.

Moreover, by using the relationship between the change in the capacitance of the capacitor and the amount of deposit deposited, the PC 90 can calculate the film thickness of the deposit attached to the surface of the quartz pipes 61a and 61b based on the change in the capacitance.

It has been taken above that the determination of beginning of fouling and the calculation of the film thickness of the deposit are carried out by the PC 90, but these may be carried out by the deposit monitoring apparatus 50, or by a user, instead of the PC 90.

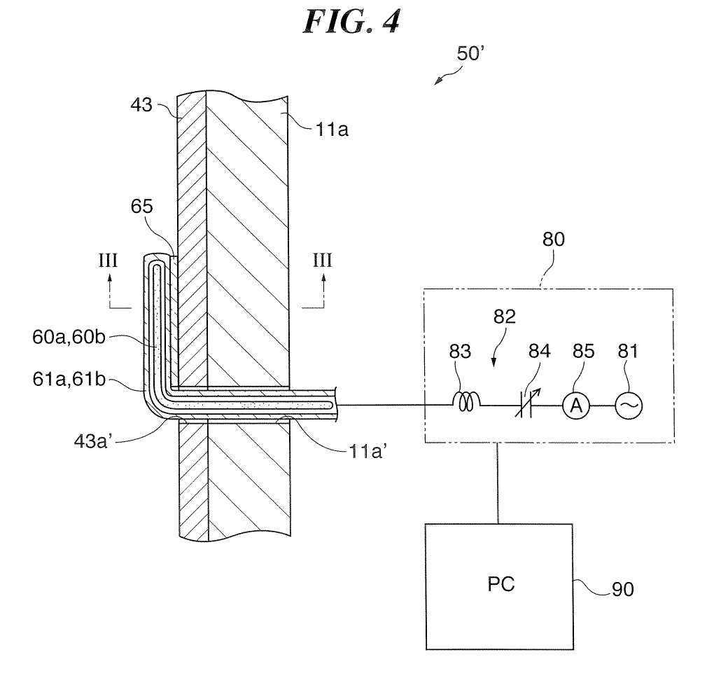

FIG. 4 is a sectional view schematically showing the construction of a first variation of the deposit monitoring apparatus 50 shown in FIG. 2.

The deposit monitoring apparatus 50′ shown in FIG. 4 is used instead of the deposit monitoring apparatus 50 shown in FIG. 2. Specifically, the deposit monitoring apparatus 50′ is constructed by removing from the chamber 11 the capacitance meter 70 used as the sensor connected to the conductive wires 60a and 60b in the deposit monitoring apparatus 50, and instead connecting an oscillator 80, described below, to the conductive wires 60a and 60b.

The oscillator 80 is comprised mainly of a crystal oscillating element 81 that oscillates at a predetermined frequency, and a resonance circuit 82 that resonates at the frequency of the crystal oscillating element 81. The resonance circuit 82 is comprised of a coil 83 connected to the conductive wires 60a and 60b, and a variable capacitor 84 connected in series with the coil 83. An ammeter 85 is connected in series between the variable capacitor 84 and the crystal oscillating element 81.

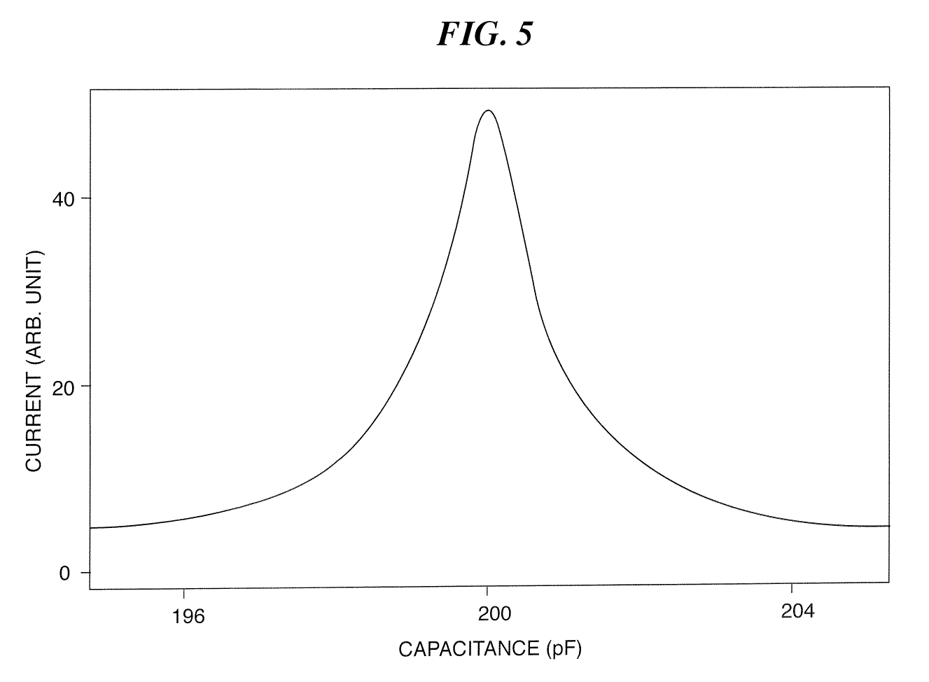

FIG. 5 is a graph showing a waveform of a current measured by the ammeter 85 of the oscillator 80 appearing in FIG. 4.

The waveform of the current measured by the ammeter 85 peaks when the resonance circuit 82 is in a resonant state with the frequency of the crystal oscillating element 81 (in FIG. 5, when the value of the capacitance of the capacitor formed by the conductive wires 60a and 60b is 200 pF).

Here, if the value of the capacitance of the capacitor changes, for example, from 200 pF to 201 pF due to attachment of deposit onto the surface of the quartz pipes 61a and 61b, then the resonant state of the resonance circuit 82 is affected. Specifically, the current, which peaked when the value of the capacitance was 200 pF, decreases dramatically, and hence the waveform shown in FIG. 5 collapses, and thus a shift arises in the resonant state of the resonance circuit 82.

The PC 90 can thus detect the beginning of fouling due to deposit in real time by detecting the shift arising in the resonant state of the resonance circuit 82, specifically the collapse in the waveform of the current measured by the ammeter 85. In this case, the PC 90 carries out cleaning of the interior of the chamber 11 as the feedback control at a suitable timing after implementation of the etching processing has been completed.

As described above, according to the present embodiment, conductive wires 60a and 60b are provided in the chamber 11 so as to form a capacitor, and the value of the capacitance of the capacitor or a shift in a resonant state is detected as data relating to the capacitance. The data relating to the capacitance reflects the beginning of fouling due to deposit or the film thickness of the deposit, and hence fouling due to deposit can be monitored in real time.

Moreover, in the deposit monitoring apparatus 50 or 50′, the only members that must be disposed in the chamber 11 for monitoring the fouling due to deposit are the conductive wires 60a and 60b and related components (the quartz pipes 61a and 61b and the quartz plate 65). The conductive wires 60a and 60b and the quartz pipes 61a and 61b are narrow/small in size, and hence the degree of freedom with regard to the installation thereof is high. As a result, replacement during maintenance is very easy, and moreover the deposit monitoring apparatus 50 or 50′ can be constructed inexpensively, and the construction can be simplified.

In the present embodiment, to improve the detection sensitivity of the sensor (the capacitance meter 70 or the oscillator 80), it is preferable to increase the length or thickness of the conductive wires 60a and 60b so as to increase the surface area thereof.

Moreover, to prevent abnormal electrical discharge in the chamber 11, it is preferable to do the following so as to try to make the plasma produced homogeneous.

Firstly, a groove for embedding the quartz pipes 61a and 61b surrounding the conductive wires 60a and 60b is formed in the deposit shield 43 or the quartz plate 65. As a result, the conductive wires 60a and 60b can be prevented from protruding out from the surface of the deposit shield 43.

Secondly, a flat portion is provided on a side of each of the quartz pipes 61a and 61b, and this flat portion is made to contact the surface of the quartz plate 65. As a result, recesses formed between the surface of the quartz plate 65 and the surface of each of the quartz pipes 61a and 61b can be made smaller in size.

Furthermore, to maintain the vacuum in the chamber 11, it is preferable to seal up space between the quartz pipes 61a and 61b and the narrow hole 43a′ or the narrow hole 11a′. For example, it is preferable to provide an O-ring between the quartz pipes 61a and 61b and the narrow hole 43a′.

Moreover, in the above embodiment, the quartz pipes 61a and 61b are provided on the surface of the quartz plate 65 which is on the deposit shield 43, but the quartz pipes 61a and 61b may be provided anywhere such as to exposed to a place where attachment of deposit occurs. For example, the quartz pipes 61a and 61b may be provided on the surface of a quartz plate 65 disposed on at least one component selected from the inner wall 11a, the ceiling portion 11b, the susceptor 12, and the ceiling electrode plate 38. In the case that the quartz pipes 61a and 61b and the quartz plate 65 are provided on the ceiling portion 11b or the ceiling electrode plate 38, detachment (maintenance) of the conductive wires 60a and 60b can easily be carried out from above. Note that the location in which the conductive wires 60a and 60b and the quartz plate 65 are provided is not limited to being in the chamber 11, but by installing the conductive wires 60a and 60b and the quartz plate 65 on a component in the chamber 11, deposit can be monitored in real time during implementation of the etching processing on a wafer W. Moreover, if the location in which the quartz plate 65 is to be provided is a component not made of a conductive material (e.g. a component made of a dielectric), then the quartz plate 65 may be omitted, the quartz pipes 61a and 61b being provided on the component directly.

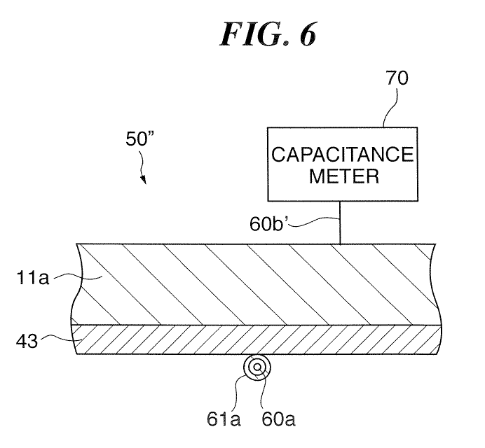

FIG. 6 is a sectional view schematically showing the construction of a second variation of the deposit monitoring apparatus 50 shown in FIG. 2.

In the deposit monitoring apparatus 50″ shown in FIG. 6, the conductive wire 60b and the quartz pipe 61b in the deposit monitoring apparatus 50 shown in FIG. 2 are omitted.

As shown in FIG. 6, in the deposit monitoring apparatus 50″, part of the chamber 11, which is made of a conductive material such as aluminum, is connected to the capacitance meter 70 via a conductive wire 60b′, which is used instead of the conductive wire 60b. In the present variation, a capacitor is thus formed by the conductive wire 60a (first conductor) and part of the chamber 11 (second conductor), the chamber 11 being used as a ground that specifies a reference potential for the capacitor.

Moreover, in the deposit monitoring apparatus 50″, the quartz plate 65 is omitted.

Note that the oscillator 80 used in the deposit monitoring apparatus 50′ may be connected in instead of the capacitance meter 70.

According to the present variation, the construction can be simplified compared with the deposit monitoring apparatus 50 or 50′.

In the embodiment described above, the substrates processed are semiconductor wafers, but the substrates processed may instead be, for example, LCD or FPD (flat panel display) glass substrates.

Moreover, the substrate processing apparatus is not limited to being an etching apparatus using plasma as described above, but may instead be a CVD apparatus.

It is to be understood that the object of the present invention may also be accomplished by supplying a computer with a storage medium in which is stored a program code of software that realizes the functions of the embodiment described above, and then causing a CPU of the computer to read out and execute the program code stored in the storage medium.

In this case, the program code itself read out from the storage medium realizes the functions of the embodiment described above, and hence the program code and the storage medium in which the program code is stored constitute the present invention.

The storage medium for supplying the program code may be any storage medium in which the program code can be stored, for example a RAM, an NV-RAM, a floppy® disk, a hard disk, a magnetic-optical disk, an optical disk such as a CD-ROM, a CD-R, a CD-RW, or a DVD (a DVD-ROM, a DVD-RAM, a DVD-RW, or a DVD+RW), a magnetic tape, a nonvolatile memory card, or a ROM. Alternatively, the program code may be supplied to the computer by being downloaded from a database or another computer, not shown, connected to the internet, a commercial network, a local area network, or the like.

Moreover, it is to be understood that the functions of the embodiment described above may be accomplished not only by executing a program code read out by a computer, but also by causing an OS (operating system) or the like which operates on the CPU to perform a part or all of the actual operations based on instructions of the program code.

Furthermore, it is to be understood that the functions of the embodiment described above may also be accomplished by writing a program code read out from a storage medium into a memory provided on an expansion board inserted into a computer or in an expansion unit connected to the computer and then causing a CPU or the like provided on the expansion board or in the expansion unit to perform a part or all of the actual operations based on instructions of the program code.

The form of the program code may be an object code, a program code executed by an interpreter, script data supplied to an OS, or the like.

What is claimed is:

1. A substrate processing apparatus comprising a processing chamber in which predetermined processing is carried out on a substrate to be processed, and a deposit monitoring apparatus that monitors deposit attached to an inner wall surface of said processing chamber, wherein:
said deposit monitoring apparatus comprises a first conductor at least part of which is provided in said processing chamber, a second conductor that is disposed separated from said first conductor, and a sensor that is connected to said first conductor and said second conductor and obtains data relating to a capacitance between said first conductor and said second conductor.

2. A substrate processing apparatus as claimed in claim 1, wherein said sensor comprises a capacitance meter that measures the capacitance between said first conductor and said second conductor.

3. A substrate processing apparatus as claimed in claim 1, wherein said sensor comprises an oscillator constituted from an oscillating element that oscillates at a predetermined frequency, and a resonance circuit that resonates at the frequency of said oscillating element.

4. A substrate processing apparatus as claimed in claim 1, further comprising:
a first dielectric that surrounds said first conductor, and
a second dielectric that surrounds said second conductor.

5. A substrate processing apparatus as claimed in claim 4, further comprising:
a third dielectric provided between said first and second conductors and the inner wall of said processing chamber such that a capacitance between said first and second conductors and the inner wall of said processing chamber is less than the capacitance between said first conductor and said second conductor.

6. A substrate processing apparatus as claimed in claim 1, further comprising:
a first dielectric that surrounds said first conductor,
wherein said second conductor comprises part of said processing chamber.

7. A substrate processing apparatus as claimed in claim 1, wherein said sensor is provided outside said processing chamber.

8. A substrate processing apparatus as claimed in claim 1, wherein said processing chamber has formed therein a groove for embedding at least said first conductor out of said first conductor and said second conductor.

9. A substrate processing apparatus as claimed in claim 1, further comprising:
a detector that detects attachment of the deposit based on the obtained data relating to the capacitance.

10. A substrate processing apparatus as claimed in claim 1, further comprising:
a controller that carries out feedback control in accordance with detection results from said detector.

11. A deposit monitoring apparatus that monitors deposit attached to an inner wall surface of a processing chamber in which predetermined processing is carried out on a substrate to be processed, the deposit monitoring apparatus comprising:
a first conductor at least part of which is provided in the processing chamber;
a second conductor that is disposed separated from said first conductor; and
a sensor that is connected to an end of said first conductor and an end of said second conductor and obtains data relating to a capacitance between said first conductor and said second conductor.

12. A deposit monitoring method for monitoring deposit attached to an inner wall surface of a processing chamber in which predetermined processing is carried out on a substrate to be processed, the deposit monitoring method comprising:
a data obtaining step of obtaining data relating to a capacitance between a first conductor at least part of which is provided in the processing chamber, and a second conductor that is disposed separated from the first conductor.
